(19) United States
(12) Patent Application Publication
(10) Pub. No.: US 2010/0007007 A1
(43) Pub. Date: Jan. 14, 2010

(54) SEMICONDUCTOR PACKAGE

(75) Inventors: Sung-hwan YOON, Asan-si (KR); Jai-kyeong Shin, Seoul (KR); Yong-nam Koh, Suwon-si (KR); Hyoung-suk Kim, Cheonan-si (KR); In-ku Kang, Suwon-si (KR); Ho-jin Lee, Yongin-si (KR); Sang-wook Park, Cheonan-si (KR); Joong-kyo Kook, Incheon (KR); Min-young Son, Asan-si (KR); Soong-yong Hur, Hwaseong-si (KR)

Correspondence Address: STANZIONE & KIM, LLP, 919 18TH STREET, N.W., SUITE 440, WASHINGTON, DC, 20006, US

(73) Assignee: Samsung Electronics Co., Ltd, Suwon-si (KR)

(21) Appl. No.: 12/496,819

(22) Filed: Jul. 2, 2009

(30) Foreign Application Priority Data
Jul. 8, 2008 (KR) 2008-66220
Feb. 2, 2009 (KR) 2009-8073

(51) Int. Cl. H01L 23/498; H01L 23/29

(52) U.S. Cl. 257/692; 257/738; 257/766; 257/788; 257/E23.119; 257/E23.069; 257/E23.023

(57) ABSTRACT

A semiconductor package includes: a semiconductor chip having a first surface, and a second surface that is opposite to the first surface and allows a semiconductor device to be formed thereon; bonding pads disposed on the second surface of the semiconductor chip; and a metal ion barrier layer disposed on the first surface of the semiconductor chip, and preventing metal ions from penetrating into the semiconductor chip through the first surface of the semiconductor chip. Accordingly, the semiconductor package can obtain a superior semiconductor device by minimizing moisture absorption and effectively blocking the penetration of metal ions.

### CROSS-REFERENCE TO RELATED APPLICATIONS

This application claims the benefit of Korean Patent Application No. 10-2008-0066220, filed on Jul. 8, 2008, and Korean Patent Application No. 10-2009-0008073, filed on Feb. 2, 2009, in the Korean Intellectual Property Office, the disclosures of which are incorporated herein in their entirety by reference.

### BACKGROUND

1. Field of the Invention

The general inventive concept relates to a semiconductor package, and more particularly, to a semiconductor package that obtains a superior semiconductor device by minimizing moisture absorption and effectively blocking the penetration of metal ions.

2. Description of the Related Art

Due to the trend towards multi-functional and miniaturized electronic products, semiconductor packages mounted on electronic products are continuously required to be miniature, lightweight, and slim. In order to meet these requirements, methods of mounting two or more semiconductor chips in one package, such as a multi-chip package and a system-in-package, have been proposed. Also, technology has developed to the point where each of semiconductor chips mounted in a package has a thickness of 50 μm or less, and even 30 μm or less.

These very thin semiconductor chips are easily damaged due to stresses applied to the semiconductor chips in fabricating processes, such as a process of attaching the chips to a substrate or a test process. In order to prevent the semiconductor chips from being damaged, a polishing process for mitigating stress may be included in a backlap process in which the semiconductor chips are processed to be thin. However, in the polishing process, the roughness of a rear surface of the semiconductor chip is greatly reduced, and thus, a smooth rear surface of the semiconductor chip is obtained. If the roughness of the rear surface of the semiconductor chip is high, the surface has a self gettering effect. However, if the roughness of the rear surface of the semiconductor chip is reduced due to the polishing process, there is a possibility that ions may penetrate into the semiconductor chip through the rear surface of the semiconductor chip, and thus, device reliability may be reduced due to the penetrated ions.

### SUMMARY

The present general inventive concept provides a semiconductor package that obtains a superior semiconductor device by minimizing moisture absorption and effectively blocking the penetration of metal ions.

Additional aspects and utilities of the present general inventive concept will be set forth in part in the description which follows and, in part, will be obvious from the description, or may be learned by practice of the general inventive concept.

Embodiments of the present general inventive concept provide a semiconductor package including: a semiconductor chip having a first surface, and a second surface that is opposite to the first surface and allows a semiconductor device to be formed thereon; bonding pads disposed on the second surface of the semiconductor chip; and a metal ion barrier layer disposed on the first surface of the semiconductor chip, and preventing metal ions from penetrating into the semiconductor chip through the first surface of the semiconductor chip.

The semiconductor package may further include: a passivation layer disposed on the second surface to expose the bonding pads; and solder balls disposed on the bonding pads. The semiconductor package may be a wafer level package (WLP).

The semiconductor package may further include: a semiconductor chip mounting unit; and lead frames electrically connected to the bonding pads, wherein the semiconductor chip is mounted on the semiconductor chip mounting unit in such a manner that the metal ion barrier layer is disposed between the semiconductor chip and the semiconductor chip mounting unit. The semiconductor chip mounting unit may be formed of copper (Cu). A nickel layer may be formed on a surface of the semiconductor chip mounting unit which contacts the metal ion barrier layer. The nickel layer may have a thickness of about 2 μm to about 20 μm. The metal ion barrier layer may be formed of a polymer resin composition including an amine group (—NH₂). The polymer resin composition may comprise an epoxy-based resin including an amine group (—NH₂). The amine group (—NH₂) may be linked to a main chain of the epoxy-based resin.

The semiconductor package may further include an adhesive layer disposed between the metal ion barrier layer and the semiconductor chip mounting unit. The adhesive layer may comprise an acrylic resin.

### BRIEF DESCRIPTION OF THE DRAWINGS

Exemplary embodiments of the present general inventive concept will be more clearly understood from the following detailed description taken in conjunction with the accompanying drawings in which:

FIG. 1 is a cross-sectional view of a semiconductor package according to an embodiment of the present general inventive concept;

FIGS. 2A through 2C are cross-sectional views illustrating a method of fabricating the semiconductor package of FIG. 1, according to an embodiment of the present general inventive concept;

FIGS. 3A and 3B are cross-sectional views illustrating semiconductor package modules according to embodiments of the present general inventive concept;

FIG. 4 is a cross-sectional view of a semiconductor package according to another embodiment of the present general inventive concept; and

FIG. 5 is a cross-sectional view of a semiconductor package according to another embodiment of the present general inventive concept.

### DETAILED DESCRIPTION OF THE EMBODIMENTS

The present general inventive concept will now be described more fully with reference to the accompanying drawings, in which exemplary embodiments of the present general inventive concept are shown. The present general inventive concept may, however, be embodied in many different forms and should not be construed as being limited to the embodiments set forth herein; rather, these embodiments are provided so that this disclosure will be thorough and complete, and will fully convey the inventive concept to one of ordinary skill in the art. Like reference numerals in the drawings denote like elements, and thus their description will be omitted. In the drawings, the thicknesses of layers and regions are exaggerated for clarity. Accordingly, the present general inventive concept is not limited to sizes or distances shown in the attached drawings. It will also be understood that when a layer is referred to as being “on” another layer or semiconductor substrate, it can be directly on the other layer or semiconductor substrate, or intervening layers may be present.

According to an embodiment of the present general inventive concept, a semiconductor package includes: a semiconductor chip having a first surface, and a second surface that is opposite to the first surface and allows a semiconductor device to be formed thereon; bonding pads disposed on the second surface; and a metal ion barrier layer disposed on the first surface and preventing metal ions from penetrating into the semiconductor chip through the first surface of the semiconductor chip.

The semiconductor package may further include a passivation layer that exposes the bonding pads, and solder balls disposed on the bonding pads. In particular, the passivation layer may be disposed on the second surface of the semiconductor chip.

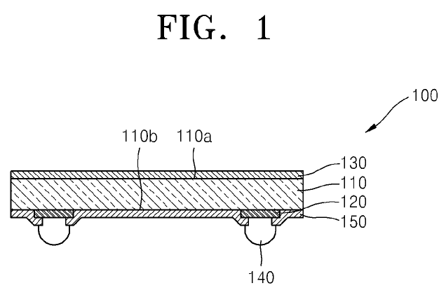

FIG. 1 is a cross-sectional view of a semiconductor package 100 according to an embodiment of the present general inventive concept.

Referring to FIG. 1, a semiconductor chip 110 has a first surface 110a and a second surface 110b that is opposite to the first surface 110a. Semiconductor devices (not shown), such as transistors, may be formed on the second surface 110b of the semiconductor chip 110. Bonding pads 120 may be formed on the second surface 110b of the semiconductor chip 110. The semiconductor devices formed on the second surface 110b of the semiconductor chip 110 may be connected to the bonding pads 120 formed on the second surface 110b through a redistribution layer. The semiconductor package 100 may be a wafer level package (WLP) as shown in FIG. 1.

Optionally, a passivation layer 150 that exposes at least a part of each of the bonding pads 120 and covers the second surface 110b may be formed on the second surface 110b of the semiconductor chip 110. For example, the passivation layer 150 may be formed of silicon oxide and/or silicon nitride using high-density plasma chemical vapor deposition.

A metal ion barrier layer 130 may be formed on the first surface 110a of the semiconductor chip 110. The metal ion barrier layer 130 may include an ion barrier material. The ion barrier material may be magnesium (Mg) oxide, aluminum (Al) oxide, titanium (Ti) oxide, zirconium (Zr) oxide, bismuth (Bi) oxide, lanthanum (La) oxide, gadolinium (Gd) oxide, samarium (Sm) oxide, thulium (Tm) oxide, europium (Eu) oxide, neodymium (Nd) oxide, erbium (Er) oxide, terbium (Tb) oxide, dysprosium (Dy) oxide, praseodymium (Pr) oxide, yttrium (Y) oxide, ytterbium (Yb) oxide, holmium (Ho) oxide, a hydrotalcite-based compound having a chemical formula of MgₓAl_{y}(OH)_{2x+3y+2z}(CO₃)₂.mH₂O (where 0<y/x≦1, 0≦z/y<1.5, and m is an integer) or MgₚAl_{q}(OH)ᵣCO₃.nH₂O (where 0.15≦q/(p+q)≦0.35, 1.8≦r/(p+q)≦2.5, and 0≦n≦5), a hydrotalcite-based sintered material having a chemical formula of Mg_{4.5}Al₂(OH)₁₃CO₃.3.5H₂O, Mg_{4.5}Al₂(OH)₁₃CO₃, Mg₅Al_{1.5}(OH)₁₃CO₃.3.5H₂O, Mg₅Al_{1.5}(OH)₁₃CO₃, Mg₆Al₂(OH)₁₆CO₃.4H₂O, Mg₆Al₂(OH)₁₈CO₃, or Mg_{4.3}Al(OH)_{12.6}CO₃.nH₂O, ethylenediaminetetraacetic acid (EDTA), 4-(2-pyridylazo) resorcinol (PAR), pyridine-2,6-dicarboxylic acid (PDCA), oxalic acid, ammonium acetate, ammonium nitrate, bismuth hydroxide, bisphenol A compound, or a triazine compound having hydroxyl or vinyl group, inorganic particles that include Mg and Al, inorganic particles that include Bi, inorganic particles that include Sb and Bi, or a combination of these materials. However, the present general inventive concept is not limited to these materials.

The ion barrier material of the metal ion barrier layer 130 may include the ion barrier material that is mixed with a matrix component. The matrix component may be, but is not limited to, a polymer compound or an inorganic compound having electrical insulating properties. The polymer compound having electrical insulating properties may be a compound such as epoxy resin, polyethylene, polypropylene, polystyrene, or polybutylene. The inorganic compound may be a metal oxide such as silica (SiO₂), alumina (Al₂O₃), zirconia (ZrO₂), titania (TiO₂), or ceria (CeO₂). In particular, when the inorganic compound is used as the matrix component, the matrix component may further include a combinative binding material such as epoxy resin.

The content of the ion barrier material in the metal ion barrier layer 130 may be about 0.1 wt % to about 20 wt % with respect to the weight of the metal ion barrier layer 130. If the content of the ion barrier material is too low, impurities, such as ions, which penetrate from the outside, may not be effectively blocked. If the content of the ion barrier material is too high, the formation of the metal ion barrier layer 130 may be difficult.

In particular, the distribution density of the ion barrier material may be in the range of about 0.1 μg/cm² to about 100 μg/cm² with respect to the first surface 110a of the semiconductor chip 110 on which the metal ion barrier layer 130 is formed. If the distribution density of the ion barrier material is too low, impurities, such as ions, which penetrate from the outside, may not be effectively blocked. If the distribution density of the ion barrier material is too high, the formation of the metal ion barrier layer 130 may be difficult.

Solder balls 140 to electrically connect the bonding pads 120 to external circuits may be formed on the bonding pads 120.

The semiconductor package 100 has high device stability and high reliability since impurities, such as ions, are effectively prevented from penetrating through the first surface 110a by the ion barrier material included in the metal ion barrier layer 130.

A method of fabricating the semiconductor package 100 of FIG. 1 will now be explained.

According to an embodiment of the present general inventive concept, a method of fabricating a semiconductor package includes: providing a semiconductor chip that has a first surface and a second surface that is opposite to the first surface and allows a semiconductor device to be formed thereon; providing bonding pads on the second surface of the semiconductor chip; and forming a metal ion barrier layer including an ion barrier material on the first surface of the semiconductor chip.

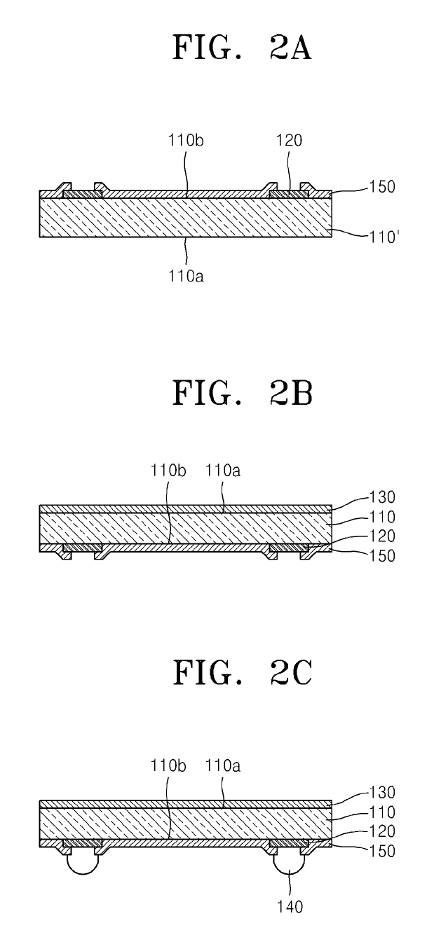

FIGS. 2A through 2C are cross-sectional views illustrating a method of fabricating the semiconductor package 100 of FIG. 1, according to an embodiment of the present general inventive concept.

Referring to FIG. 2A, a semiconductor chip 110′ having the first surface 110a and the second surface 110b that is opposite to the first surface 110a and allows a semiconductor device to be formed thereon is provided. In order to provide the semiconductor chip 110′, semiconductor devices are formed on a wafer (not shown) using a well-known method, and then the semiconductor devices are individualized by dicing the wafer to obtain the semiconductor chip 110′.

Optionally, the bonding pads 120 are formed on appropriate positions of the first surface 110a through redistribution, and the passivation layer 150 is formed to expose at least a part of each of the bonding pads 120. As described above, the passivation layer 150 may be obtained by forming a silicon oxide layer and/or a silicon nitride layer using a high-density plasma chemical vapor deposition process. The bonding pads 120 may be formed of a metal such as aluminum (Al) or copper (Cu). However, the present general inventive concept is not limited to these materials.

Optionally, the semiconductor chip 110′ may be thinned by performing a backlap process on the first surface 110a of the semiconductor chip 110′. Also, the backlap process may include a polishing process which not only reduces the thickness of the semiconductor chip 110′, but also reduces the roughness of the first surface 110a of the semiconductor chip 110′.

Referring to FIG. 2B, the metal ion barrier layer 130 may be formed on the first surface 110a of the semiconductor chip 110′. The metal ion barrier layer 130 may be formed by forming a liquid or slurry phase metal ion blocking composition, applying the metal ion blocking composition to the first surface 110a of the semiconductor chip 110′, and hardening the metal ion blocking composition. Alternatively, the metal ion barrier layer 130 may be formed by forming a metal ion blocking tape and attaching the metal ion blocking tape to the first surface 110a of the semiconductor chip 110′.

The respective methods of forming the metal ion barrier layer 130 will now be explained in more detail.

### Method Using Metal Ion Blocking Composition

The metal ion blocking composition may include a matrix component and an ion barrier material. The ion barrier material has been described above, and thus a detailed description thereof will not be given. The matrix component may be, but is not limited to, a polymer compound having electrical insulating properties or an inorganic material. The polymer compound having electrical insulating properties may be a compound such as epoxy resin, polyethylene, polypropylene, polystyrene, or polybutylene. The inorganic material may be a metal oxide such as SiO₂, Al₂O₃, ZrO₂, TiO₂, or CeO₂. In particular, if the inorganic material is used as the matrix component, the matrix component may further include a combinative binding material such as epoxy resin.

Although a mixing ratio between the matrix component and the ion barrier material is not specifically defined, as described later, the content of the ion barrier material included in the metal ion barrier layer 130 may be controlled to be about 0.1 wt % to about 20 wt % with respect to the weight of the metal ion barrier layer 130.

If epoxy resin is used as the matrix component, that is, the polymer compound having electrical insulating properties, the molecular weight or molecular structure of the epoxy is not specifically limited, and the epoxy resin may be, for example, a bisphenol-A type epoxy resin, an ortho-cresol novolak type epoxy resin, a naphthol novolak type epoxy resin, a phenol aralkyl type epoxy resin, a dicyclopentadiene modified phenol type epoxy resin, a bi-phenyl type epoxy resin, a stilbene type epoxy resin, or a mixture of these materials. However, the content of Na ions or Cl ions may be minimized in consideration of waterproof reliability and device reliability against ions, and, for example, may be about 100 g/eq to about 500 g/eq on an epoxy equivalent basis.

If necessary, various additives may be mixed in the metal ion blocking composition. For example, the additive may be an imidazole compound, a hardening catalyst such as a third class amine compound or a phosphorus-based compound, a molybdate zinc doped zincoxide, a molybdate zinc doped talc, a phosphazene compound, a flame retardant such as magnesium hydroxide (MgOH) or aluminum hydroxide (Al₂(OH)₃), or a thermoplastic elastomer.

Optionally, the metal ion blocking composition may include a hardening agent such as phenol resin, and may include a hardening promoter to promote the hardening reaction of the hardening agent. The phenol resin may have at least one naphthalene ring that is substituted or non-substituted in a molecule, and the hardening promoter may be, for example, triphenylphosphine, tributylphosphine, tri(p-methylphenyl)phosphine, tri(nonylphenyl)phosphine, trimethylborane, tetraphenylphosphine, tetraphenylborate, triethylamine, benzyldimethylamine, α-methylbenzyldimethylamine, 2-methylimidazole, 2-phenylimidazole, or 2-phenyl-4-methylimidazole.

The metal ion blocking composition may be formed on the first surface 110a of the semiconductor chip 110′ using a well-known method, e.g., a doctor blade method.

### Method Using Metal Ion Blocking Tape

The metal ion blocking tape may be formed by sequentially forming the metal ion blocking composition and an adhesive layer on a tape material, forming a releasing agent on the adhesive layer, and forming a metal ion blocking tape on the releasing agent. That is, in order to form the metal ion barrier layer 130, the metal ion blocking tape is removed. At this time, the releasing agent may be removed along with the metal ion blocking tape. Next, an exposed surface of the adhesive layer is attached to the first surface 110a to form the metal ion barrier layer 130.

The tape material may be a well-known polymer film, such as polyethylene or polypropylene. The releasing agent may be a well-known material, for example, a high-grade fatty acid, a high-grade fatty acid metallic salt, ester-based wax, or polyethylene-based wax. These materials may be used alone or by mixing at least two of these materials.

The content of the ion barrier material may be controlled to be about 0.1 wt % to about 20 wt % with respect to the weight of the metal ion barrier layer 130. If the content of the ion barrier material is too low, impurities, such as ions, which penetrate from the outside, may not be effectively blocked. If the content of the ion barrier material is too high, the formation of the metal ion barrier layer 130 may be difficult.

In particular, the distribution density of the ion barrier material may be controlled to be in the range of about 0.1 μg/cm² to about 100 μg/cm² with respect to the first surface 110a on which the metal ion barrier layer 130 is formed. If the distribution density of the ion barrier material is too low, the penetration of impurities, such as ions, from the outside may not be effectively blocked. If the distribution density of the ion barrier material is too high, the formation of the metal ion barrier layer 130 may be difficult.

Referring to FIG. 2C, the solder balls 140 may be formed on the bonding pads 120 using a well-known method in the art. As described above, the bonding pads 120 may be formed of Al or Cu. Optionally, an under bump metallurgy (UBM) layer may further be formed on the bonding pads 120 so that the solder balls 140 can be easily attached to the bonding pads 120 and the components of the solder balls 140 can be prevented from penetrating into the bonding pads 120.

A semiconductor package can be fabricated using the aforesaid method.

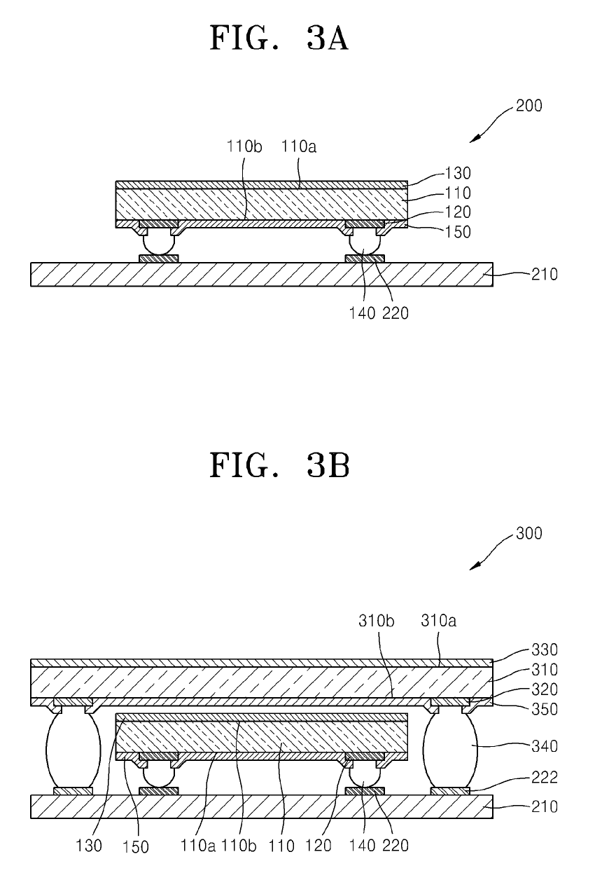

Semiconductor package modules each including the semiconductor package 100 according to embodiments of the present general inventive concept will now be explained. FIG. 3A is a cross-sectional view of a semiconductor package module 200 according to an embodiment of the present general inventive concept.

Referring to FIG. 3A, a first semiconductor package 200 having a first dimension is mounted on a substrate 210 that includes connection terminals 220. The first semiconductor package 200 may be the semiconductor package 100 of FIG. 1, and the substrate 210 may be a printed circuit substrate. Optionally, the substrate 210 may be a system-in-package (SIP) frame. The first semiconductor package 200 may be connected to the substrate 210 since the solder balls 140 are directly electrically connected to the substrate 210.

FIG. 3B is a cross-sectional view of a semiconductor package module 300 according to another embodiment of the present general inventive concept.

Referring to FIG. 3B, the semiconductor package module 300 includes a first semiconductor package having a first dimension formed on the substrate 210. Also, the semiconductor package module 300 includes a second semiconductor package having a second dimension, which is greater than the first dimension, formed over the first semiconductor package.

The second semiconductor package may include: a semiconductor chip 310 having a first surface 310a and a second surface 310b that is opposite to the first surface 310a and allows a semiconductor device to be formed thereon; bonding pads 320 formed on the second surface 310b of the semiconductor chip 310; a metal ion barrier layer 330 formed on the first surface 310a of the semiconductor chip 310 and includes an ion barrier material; a passivation layer 350 covering the second surface 310b of the semiconductor chip 310 while exposing at least a part of each of the bonding pads 320; and solder balls 340 formed on the bonding pads 320.

The semiconductor package modules 200 and 300 of FIGS. 3A and 3B have high stability with respect to impurities such as ions that penetrate from the outside and high reliability.

According to another embodiment of the present general inventive concept, a semiconductor package includes: a semiconductor chip having a first surface, and a second surface that is opposite to the first surface and allows a semiconductor device to be formed thereon; bonding pads disposed on the second surface of the semiconductor chip; and a metal ion barrier layer disposed on the first surface of the semiconductor chip and preventing metal ions from penetrating into the semiconductor chip through the first surface of the semiconductor chip. The semiconductor package may further include: a semiconductor chip mounting unit; and lead frames electrically connected to the bonding pads, wherein the semiconductor chip is disposed over the semiconductor chip mounting unit in such a manner that the metal ion barrier layer is disposed between the semiconductor chip and the semiconductor chip mounting unit.

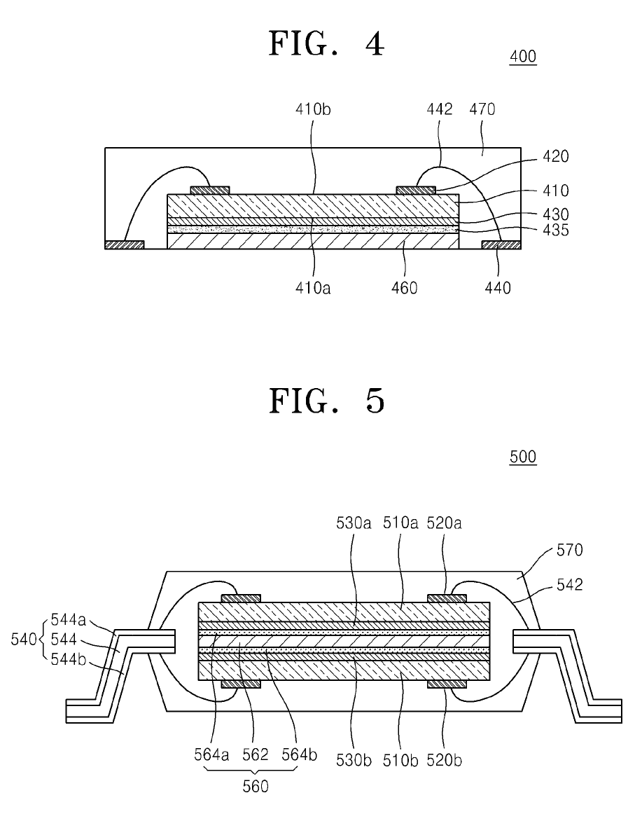

FIG. 4 is a cross-sectional view of a semiconductor package 400 according to yeet another embodiment of the present general inventive concept. Referring to FIG. 4, a semiconductor chip 410 having a first surface 410a and a second surface 410b that is opposite to the first surface 410a is mounted on a semiconductor chip mounting unit 460. Semiconductor devices, such as transistors, may be formed on the second surface 410b of the semiconductor chip 410. In particularly, a metal ion barrier layer 430 may be disposed between the semiconductor chip mounting unit 460 and the semiconductor chip 410.

The semiconductor package 400 of FIG. 4 may be a chip scale package (CSP).

The semiconductor chip mounting unit 460 may be formed of a Fe/Ni alloy or Cu. In particular, the semiconductor chip mounting unit 460 may be formed of Cu. Optionally, a nickel layer may be formed on a surface of the semiconductor chip mounting unit 460. The nickel layer may have a thickness of about 2 μm to about 20 μm. If the semiconductor chip mounting unit 460 is formed of Cu, the nickel layer can prevent Cu ions from penetrating into the semiconductor chip 410. Accordingly, if the thickness of the nickel layer is too low, metal ions including Cu ions that penetrate into the semiconductor chip 410 may not be effectively blocked. If the thickness of the nickel layer is too high, metal ion blocking effect due to the formation of the nickel layer is saturated which would be cost-ineffective.

The nickel layer may be formed on the semiconductor chip mounting unit 460 using, for example, but not limited to, a plating technique. The nickel layer may be formed on both surfaces of the semiconductor chip mounting unit 460, or only on a surface of the semiconductor chip mounting unit 460 which contacts the metal ion barrier layer 430. That is, the nickel layer may be formed at least on the surface of the semiconductor chip mounting unit 460 which contacts the metal ion barrier layer 430.

The metal ion barrier layer 430, which is disposed between the semiconductor chip 410 and the semiconductor chip mounting unit 460 and can prevent metal ions from passing therethrough, may include an ion barrier material as described above. In particular, the metal ion barrier layer 430 may be formed of a polymer resin composition including an amine group (—NH₂). The polymer resin composition may be an epoxy-based resin. In particular, the amine group may be linked to a main chain of the epoxy-based resin.

An adhesive layer 435 may be further disposed between the metal ion barrier layer 430 and the semiconductor chip mounting unit 460.

The adhesive layer 435 may be formed of a thermoplastic resin, or a combination of a thermoplastic resin and a thermosetting resin.

The thermoplastic resin may be natural rubber, butyl rubber, isoprene rubber, chloroprene rubber, ethylene-vinyl acetate copolymer, ethylene-acrylic acid copolymer, ethylene-acrylic acid ester copolymer, polybutadiene resin, polycarbonate resin, thermoplastic polyimide resin, polyamide resin such as nylon-6 or nylon-66, phenoxy resin, acrylic resin, saturated polyester resin such as polyethylene terephthalate (PET) or polybutylene terephthalate (PBT), polyamide-imide resin, or fluorine resin. These materials may be used alone or by mixing at least two of these materials. In particular, the adhesive layer 435 may include an acrylic resin that has a small amount of ionic impurities and high heat resistance, and ensures high device reliability.

The acrylic resin may be a polymer formed by the polymerization of a monomer having general formula R—(CO)—CH═CH₂, and particularly, may be a polymer including at least one type of (meth)acrylic acid having a straight or branched chain alkyl group with less than 30 carbon atoms, particularly, from 4 to 18 carbon atoms. For example, the acrylic resin may be a carboxyl group-containing monomer such as acrylic acid, methacrylic acid, carboxyethyl acrylate, carboxypentyl acrylate, itaconic acid, maleic acid, fumaric acid, or crotonic acid, an acid anhydride monomer such as maleic anhydride or itaconic anhydride, a hydroxyl group-containing monomer such as 2-hydroxyethyl(meth)acrylate, 2-hydroxypropy (meth)acrylate, or 4-hydroxybutyl(meth)acrylate, a sulfonic acid-containing monomer such as styrenesulfonic acid, allylsulfonic acid, 2-(meth)acrylamide-2-methylpropane sulfonic acid, (meth)acrylamide propanesulfonic acid, sulfopropyl(meth)acrylate, or (meth)acryloyloxy naphthalene sulfonic acid, or a phosphate-containing monomer such as 2-hydroxyethylacryloyl phosphate.

The thermosetting resin may be phenol resin, amino resin, unsaturated polyester resin, epoxy resin, polyurethane resin, silicon resin, or thermosetting polyimide resin. These materials may be used alone or by mixing at least two of these materials. In particular, the thermosetting resin may be phenol resin.

The semiconductor package 400 may be sealed using a molding resin 470. The molding resin 470 may be a well-known molding material, for example, an epoxy molding compound (EMC).

The bonding pads 420 may be electrically connected through wires 442 to leads 440 that are exposed to the outside of the molding resin 470.

FIG. 5 is a cross-sectional view of a semiconductor package 500 according to still another embodiment of the present general inventive concept. Referring to FIG. 5, a first semiconductor chip 510a and a second semiconductor chip 510b are respectively mounted on a top surface and a bottom surface of a semiconductor chip mounting unit 560. Bonding pads 520a and 520b may be respectively formed on surfaces of the first semiconductor chip 510a and the second semiconductor chip 510b, and semiconductor devices may be formed on the surfaces of the first semiconductor chip 510a and the second semiconductor chip 510b on which the bonding pads 520a and 520b are formed. Metal ion barrier layers 530a and 530b may be respectively formed between the semiconductor chip mounting unit 560 and the first semiconductor chip 510a and between the semiconductor chip mounting unit 560 and the second semiconductor chip 510b.

The semiconductor package 500 of FIG. 5 may be a flat package (FP) or a quad flat package (QFP).

The semiconductor chip mounting unit 560 may be formed of a Fe/Ni alloy or Cu as described above, and particularly may be formed of Cu. Nickel layers 564a and 564b may be respectively formed on the top surface and the bottom surface of the semiconductor chip mounting unit 560.

The metal ion barrier layers 530a and 530b respectively disposed between the semiconductor chip mounting unit 560 and the first semiconductor chip 510a and between the semiconductor chip mounting unit 560 and the second semiconductor chip 510b prevent metal ions from passing therethrough as described above and thus a detailed explanation thereof will not be given.

Adhesive layers (not shown) may be further disposed between the semiconductor chip mounting unit 560 and the metal ion barrier layers 530a and between the semiconductor chip mounting unit 560 and the metal ion barrier layer 530b.

As shown in FIG. 5, each of leads 540 of the semiconductor package 500 may include a core lead 542 and nickel layers 544a and 544b formed on the core lead 544. In particular, the thickness of each of the nickel layers 544a and 544b formed on the core lead 544 may be substantially the same as the thickness of each of nickel layers 564a and 564b formed on the semiconductor chip mounting unit 560.

The semiconductor package 500 may be sealed using a molding resin 570. The molding resin 570 may be a well-known molding material, for example, EMC.

The bonding pads 520a and 520b may be electrically connected through wires 542 to the leads 540 that are exposed to the outside of the molding resin 570.

As described above, since the metal ion barrier layers 530a and 530b are formed between the semiconductor chip mounting unit 560 and the semiconductor chip 510a and between the semiconductor chip mounting unit 560 and the semiconductor chip 510b, and since the nickel layers 564a and 564b are formed on the top surface and the bottom surface of the semiconductor chip mounting unit 560, the metal ion barrier layers 530a and 530b and the nickel layers 564a and 564b can effectively prevent metal ions and/or moisture from penetrating into the semiconductor chips 510a and 510b.

While the configuration and effect of the present general inventive concept will now be explained in detail with reference to an experimental example and a comparative example, the experimental example and the comparative example should be considered in a descriptive sense only and not for purposes of limitation.

### Comparative Example 1

A semiconductor chip was formed on a semiconductor chip mounting unit that was formed of Cu. A polymer resin layer formed by the polymerization of glycidyl ether was formed between the semiconductor chip mounting unit and the semiconductor chip. Next, a resultant structure was sealed using EMC to form 96 CSPs.

### Experimental Example 1

A semiconductor chip was formed on a semiconductor chip mounting unit which was formed of Cu and on which a nickel layer having a thickness of 4 μm was formed. An epoxy polymer resin layer including an amine group (—NH₂) that was linked to a main chain was formed between the semiconductor chip mounting unit and the semiconductor chip. The epoxy polymer resin is commonly available and is obvious to one of ordinary skill in the art. Next, a resultant structure was sealed using EMC to form 96 CSPs.

An experiment was performed to check the occurrence of charge loss and delamination between the semiconductor chip and the semiconductor chip mounting unit of each of the semiconductor packages of the comparative example 1 and the experimental example 1, and results of the experiment are shown in Table 1. The experiment was performed by writing data to the semiconductor chips, leaving the semiconductor chips at a relative humidity of 85% and a temperature of 85oC for 24 hours, and performing infrared (IR) reflow three times.

TABLE 1

| | Charge loss (%) | Delamination (%) |
|---|---|---|
| Experimental example 1 | 0 | 0 |
| Comparative example 1 | 96 | 43 |

Accordingly, the CSPs according to the experimental 1 that is based on the inventive concept greatly reduced charge loss due to Cu ions and delamination due to moisture absorption.

The semiconductor package according to the various embodiments of the present general inventive concept can obtain a superior semiconductor device by minimizing moisture absorption and effectively preventing the penetration of metal ions.

While the present general inventive concept has been particularly shown and described with reference to exemplary embodiments thereof, it will be understood by one of ordinary skill in the art that various changes in form and details may be made therein without departing from the spirit and scope of the general inventive concept as defined by the following claims.

What is claimed is:

1. A semiconductor package comprising:
a semiconductor chip having a first surface, and a second surface that is opposite to the first surface and allows a semiconductor device to be formed thereon;
bonding pads disposed on the second surface of the semiconductor chip; and
a metal ion barrier layer disposed on the first surface of the semiconductor chip, and preventing metal ions from penetrating into the semiconductor chip through the first surface of the semiconductor chip.

2. The semiconductor package of claim 1, further comprising:
a passivation layer disposed on the second surface to expose the bonding pads; and
solder balls disposed on the bonding pads.

3. The semiconductor package of claim 2, wherein the semiconductor package is a wafer level package (WLP).

4. The semiconductor package of claim 1, further comprising:
a semiconductor chip mounting unit; and
lead frames electrically connected to the bonding pads,
wherein the semiconductor chip is mounted on the semiconductor chip mounting unit in such a manner that the metal ion barrier layer is disposed between the semiconductor chip and the semiconductor chip mounting unit.

5. The semiconductor package of claim 4, wherein the semiconductor chip mounting unit is formed of copper (Cu).

6. The semiconductor package of claim 5, wherein a nickel layer is formed on a surface of the semiconductor chip mounting unit which contacts the metal ion barrier layer.

7. The semiconductor package of claim 6, wherein the metal ion barrier layer is formed of a polymer resin composition including an amine group (—NH₂).

8. The semiconductor package of claim 7, wherein the nickel layer has a thickness of about 2 μm to about 20 μm.

9. The semiconductor package of claim 7, wherein the polymer resin composition comprises an epoxy-based resin including an amine group (—NH₂).

10. The semiconductor package of claim 9, further comprising:
an adhesive layer disposed between the metal ion barrier layer and the semiconductor chip mounting unit.

11. The semiconductor package of claim 10, wherein the amine group (—NH₂) is linked to a main chain of the epoxy-based resin, and the adhesive layer comprises an acrylic resin.
